(19) United States
(12) Patent Application Publication
(10) Pub. No.: US 2026/0089906 A1
(43) Pub. Date: Mar. 26, 2026

(54) PRODUCTION ORDER DETERMINATION SYSTEM AND PRODUCTION ORDER DETERMINATION METHOD

(71) Applicant: FUJI CORPORATION, Chiryu (JP)

(72) Inventor: Yukitoshi MORITA, Okazaki-shi (JP)

(73) Assignee: FUJI CORPORATION, Chiryu (JP)

(21) Appl. No.: 19/109,695

(22) PCT Filed: Oct. 27, 2022
(86) PCT No.: PCT/JP2022/040162

§ 371 Date: Mar. 7, 2025

(51) Int. Cl. H05K 13/08; G05B 19/418

(52) U.S. Cl. CPC H05K 13/085; G05B 19/41865; G05B 2219/45026

(57) ABSTRACT

A system for determining a production order includes a first circuit board selection section, and a first circuit board determination section. The first circuit board determination section calculates a degree of commonality between component types of multiple components used when the circuit board of the board type selected by the first circuit board selection section is produced and component types of multiple components used when a circuit board of a board type not selected by the first circuit board selection section is produced, and determines a circuit board of a board type having the highest calculated degree of commonality in components as the circuit board of the board type to be produced next to the circuit board of the board type selected by the first circuit board selection section.

### TECHNICAL FIELD

A technique disclosed in the present description relates to a board production facility that mounts components of multiple types on a board to produce a circuit board. In particular, the present disclosure relates to a technique for determining a production order when circuit boards of multiple board types are produced for each board type in an order.

### BACKGROUND ART

In a board production facility that produces a circuit board, circuit boards of multiple board types are usually produced. The types and the number of components mounted on a board in the board production facility differ depending on a board type of the circuit board. Therefore, in order to produce a circuit board of a certain board type, it is necessary to prepare components necessary for producing the circuit board of the board type in the board production facility. In order to reduce the number of times of work of preparing components in such a board production facility, circuit boards are produced for each board type in an order when circuit boards of multiple board types are produced.

Here, when production of circuit boards of a certain board type is completed and circuit boards of another board type are produced next, work of switching components to be prepared in the board production facility from components necessary for the production of the circuit boards of the certain board type to components necessary for producing the circuit boards of the other board type (so-called setup change work) is required. When the setup change work takes a long time, a time during which the board production facility is stopped occurs, and an operation rate of the board production facility is reduced. For this reason, there has been developed a technique for determining a production order when circuit boards of multiple board types are produced for each board type in an order (JP-A-2018-37592). In the technique disclosed in JP-A-2018-37592, from among circuit boards of multiple types as production targets, circuit boards of a board type in which a production volume is large are set to be a reference, and circuit boards of a board type having a high degree of commonality in components with respect to the circuit boards of the board type as the reference are determined as circuit boards of a board type to be produced next.

### BRIEF SUMMARY

### Technical Problem

In the above-described related art, the production order is determined with the circuit boards of the board type in which the production volume is large as the reference. That is, the circuit boards of the board type in which the production volume is large are produced first, and circuit boards of a board type in which the production volume is small are produced later. Since a production time of the circuit boards of the board type in which the production volume is small is short, production preparation for circuit boards of a board type to be produced next needs to be performed during the short production time. Here, a time required for production preparation for circuit boards is determined more by types of components than by a production volume. For this reason, in the related art, it may be impossible to complete production preparation for circuit boards of a board type to be produced next to circuit boards of a board type in which a production volume is small while producing the circuit boards of the board type in which the production volume is small. When such a situation occurs, it is necessary to stop the board production facility for the production preparation for the circuit boards.

The present description provides a technique for reducing stops of a board production facility for production preparation for circuit boards to be produced next by making the production preparation for the circuit boards easy to complete during previous production of circuit boards.

### Solution to Problem

A first production order determination system disclosed in the present description determines a production order when circuit boards of multiple board types are produced for each board type in an order in a board production facility that mounts components of multiple types on boards to produce circuit boards. The system includes a first circuit board selection section configured to select a circuit board of a board type with the shortest production time from among the circuit boards of the multiple board types, and a first circuit board determination section configured to determine a circuit board of a board type to be produced next to the circuit board of the board type selected by the first circuit board selection section. The first circuit board determination section is configured to calculate a degree of commonality between component types of multiple components used when the circuit board of the board type selected by the first circuit board selection section is produced and component types of multiple components used when a circuit board of a board type not selected by the first circuit board selection section is produced, for each board type for the circuit board of the board type not selected by the first circuit board selection section, and determine a circuit board of a board type having the highest calculated degree of commonality in components as the circuit board of the board type to be produced next to the circuit board of the board type selected by the first circuit board selection section.

In the first production order determination system, the circuit board of the board type with the shortest production time is selected, and the circuit board of the board type having the highest calculated degree of commonality in components with respect to the selected circuit board of the board type is determined to be produced next to the circuit board of the board type with the shortest production time. That is, when the circuit board of the board type with the shortest production time is produced, it is necessary to shorten a time for production preparation for the circuit board to be produced next. Therefore, the circuit board of the board type having the highest degree of commonality in components with respect to the circuit board of the board type with the shortest production time is set as the circuit board to be produced next to the circuit board of the board type with the shortest production time. Accordingly, the production preparation for the next circuit board is easily completed during the production of the circuit board of the board type with the shortest production time, and it is possible to reduce stops of the board production facility for the production preparation for the circuit board.

In addition, a first production order determination method disclosed in the present description is a method of determining a production order when circuit boards of multiple board types are produced for each board type in an order in a board production facility that mounts components of multiple types on boards to produce circuit boards, the method including a first circuit board selection step of selecting a circuit board of a board type with the shortest production time from among the circuit boards of the multiple board types, and a first circuit board determination step of determining a circuit board of a board type to be produced next to the circuit board of the board type selected by the first circuit board selection step. In the first circuit board determination step, a degree of commonality between component types of multiple components used when the circuit board of the board type selected by the first circuit board selection step is produced and component types of multiple components used when a circuit board of a board type not selected by the first circuit board selection step is produced is calculated for each board type for the circuit board of the board type not selected by the first circuit board selection step, and a circuit board of a board type having the highest calculated degree of commonality in components is determined as the circuit board of the board type to be produced next to the circuit board of the board type selected by the first circuit board selection step. Also with the method, the same effects as those of the first production order determination system can be obtained.

In addition, a second production order determination system disclosed in the present description determines a production order when circuit boards of multiple board types are produced for each board type in an order in a board production facility that mounts components of multiple types on boards to produce circuit boards. The system includes a first circuit board selection section configured to select a circuit board of a board type with the shortest production time from among the circuit boards of the multiple board types, and a determination section configured to determine the circuit board of the board type selected by the first circuit board selection section as a circuit board of a board type to be finally produced.

In the second production order determination system, the circuit board of the board type with the shortest production time is selected, and the selected circuit board of the board type is determined as the circuit board of the board type to be finally produced. Accordingly, when the circuit board of the board type with the shortest production time is produced, it is not necessary to perform the production preparation for the circuit board of another board type. For this reason, it is possible to reduce the stops of the board production facility for the production preparation for the circuit board.

In addition, a second production order determination method disclosed in the present description is a method that determines a production order when circuit boards of multiple board types are produced for each board type in an order in a board production facility that mounts components of multiple types on boards to produce circuit boards, the method including a first circuit board selection step of selecting a circuit board of a board type with the shortest production time from among the circuit boards of the multiple board types, and a step of determining the circuit board of the board type selected by the first circuit board selection step as a circuit board of a board type to be finally produced. Also with the method, the same effects as those of the second production order determination system can be obtained.

### BRIEF DESCRIPTION OF DRAWINGS

FIG. 1 is a block diagram showing a configuration of a production order determination system according to an example.

FIG. 2 is a diagram showing a data structure of production information data.

FIG. 3 is a flowchart showing a procedure of production order determination processing.

FIG. 4 is a diagram specifically showing a procedure for determining a production order.

FIG. 5 is a diagram specifically showing a procedure for determining the production order.

FIG. 6 is a diagram specifically showing a procedure for determining the production order.

FIG. 7 is a diagram specifically showing a procedure for determining the production order.

FIG. 8 is a diagram specifically showing a procedure for determining the production order.

FIG. 9 is a diagram specifically showing a procedure for determining the production order.

FIG. 10 is a diagram specifically showing a procedure for determining the production order.

FIG. 11 is a diagram specifically showing a procedure for determining the production order.

FIG. 12 is a diagram specifically showing a procedure for determining the production order.

FIG. 13 is a flowchart showing a procedure of production order determination processing according to a modification example.

### DESCRIPTION OF EMBODIMENTS

The first production order determination system disclosed in the present description may further include a second circuit board selection section configured to select, when there are multiple circuit boards of undetermined board types for which a circuit board of a board type to be produced next has not been determined, the circuit board of the board type with the shortest production time from among the multiple circuit boards of the undetermined board types, and a second circuit board determination section configured to determine a circuit board of a board type to be produced next to the circuit board of the board type selected by the second circuit board selection section. The second circuit board determination section may be configured to calculate a degree of commonality between component types of multiple components used when the circuit board of the board type selected by the second circuit board selection section is produced and component types of multiple components used when a circuit board of a board type for which a circuit board of a board type to be produced in a previous process is not determined and which is producible next to the circuit board of the board type selected by the second circuit board selection section is produced, for each board type for the circuit board of the board type which is producible, and determine a circuit board of a board type having the highest calculated degree of commonality in components as the circuit board of the board type to be produced next to the circuit board of the board type selected by the second circuit board selection section. With such a configuration, when there are the multiple circuit boards of the undetermined board types for which the circuit board of the board type to be produced next has not been determined, it is possible to suitably determine the circuit board of the board type to be produced next to the circuit board of the board type with the shortest production time among them.

In the first production order determination system disclosed in the present description, the selection of the circuit board of the board type performed by the second circuit board selection section and the determination of the circuit board of the board type performed by the second circuit board determination section may be repeatedly executed when there are the multiple circuit boards of the undetermined board types for which the circuit board of the board type to be produced next has not been determined. With such a configuration, it is possible to suitably determine the circuit board of the board type to be produced next in order from the circuit board of the board type in which the production time is shorter.

The first production order determination system disclosed in the present description may further include a third circuit board selection section configured to select, when there are multiple circuit boards of undetermined board types for which a circuit board of a board type to be produced next has not been determined, a circuit board of a certain board type from among the multiple circuit boards of the undetermined board types in accordance with a selection condition set in advance, and a third circuit board determination section configured to determine a circuit board of a board type to be produced next to the circuit board of the board type selected by the third circuit board selection section. The third circuit board determination section may be configured to calculate a degree of commonality between component types of multiple components used when the circuit board of the board type selected by the third circuit board selection section is produced and component types of multiple components used when a circuit board of a board type for which a circuit board of a board type to be produced in a previous process is not determined and which is producible next to the circuit board of the board type selected by the third circuit board selection section is produced, for each board type for the circuit board of the board type which is producible, and determine a circuit board of a board type having the highest calculated degree of commonality in components as the circuit board of the board type to be produced next to the circuit board of the board type selected by the third circuit board selection section.

### EXAMPLE

Hereinafter, production order determination system 10 according to an example will be described with reference to the drawings. Production order determination system 10 determines a production order of circuit boards produced by a component mounter (an example of a board production facility). Before describing production order determination system 10 in detail, first, the component mounter will be briefly described.

The component mounter produces a circuit board by mounting components on a board. The component mounter includes multiple component feeders detachably attached to multiple slots, and a mounting unit that mounts components supplied from the multiple component feeders on the board. Multiple components of types set in advance are accommodated in the component feeders. Since components of multiple types are mounted on the board, multiple component feeders corresponding to components of multiple types mounted on the board are attached to the slots. The components of multiple types supplied from the multiple component feeders are mounted on the board by a mounting unit. Thus, a circuit board on which the components of multiple types are mounted is produced.

Here, in the component mounter, circuit boards of multiple board types are produced. The type and the number of components mounted on the board are different depending on the board type of the circuit board. Therefore, when the board type of the circuit board produced by the component mounter is changed, the type and the number of components mounted on the board are changed accordingly, and the component feeders attached to the slots need to be changed. In order to reduce the number of times of the change of the component feeders in the component mounter, the circuit boards of the multiple types produced by the component mounter are produced for each board type in an order.

As is clear from the above description, when the type of the components mounted on the circuit boards produced immediately before and the type of the components mounted on the circuit boards to be produced next are the same, it is not necessary to change the component feeders. Therefore, when a degree of commonality in the components is high between the circuit boards produced immediately before and the circuit boards to be produced next, the number of times of change of the component feeders is reduced, and change work thereof can be performed in a short time. On the other hand, when the degree of commonality in the components is low between the circuit boards produced immediately before and the circuit boards to be produced next, the number of times of change of the component feeders increases, and the change work requires a long time. The work of changing the component feeders attached to the slots of the component mounter can be performed by a worker or a robot.

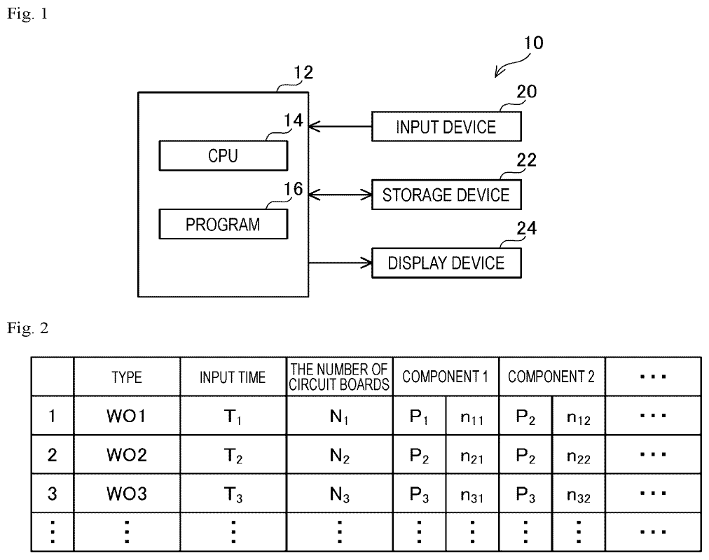

Next, production order determination system 10 that determines the production order when the circuit boards of the multiple board types are produced by the component mounter will be described. As shown in FIG. 1, production order determination system 10 includes input device 20, storage device 22, display device 24, and calculation device 12 connected to devices 20, 22, and 24.

Input device 20 inputs production information on circuit boards produced by the component mounter. The production information input from input device 20 is transmitted to calculation device 12 and stored in storage device 22 as production information data. As input device 20, a device such as a keyboard or a mouse connected to calculation device 12 can be used, or a terminal (computer) or the like communicably connected to calculation device 12 may be used as input device 20.

Storage device 22 stores the above production information data and various data necessary for producing the circuit boards with the component mounter. As shown in FIG. 2, the production information data includes, for each board type of the circuit boards produced by the component mounter, data related to the circuit board of the board type. Specifically, the production information data includes, for each board type (WO1, WO2, . . . ) of the circuit boards, a time (T₁, T₂, . . . ) in which production information related to the circuit boards of the board type is input, the number (N₁, N₂, . . . ) by which the circuit boards are produced, component types (P₁, P₂, . . . ) of multiple components to be mounted on the circuit boards, and the number (nᵢⱼ (i and j are integers)) by which the components are mounted. For example, first production information data shown in FIG. 2 relates to circuit boards of board type WO1, is input to calculation device 12 at time T₁, and shows that N₁ circuit boards of board type WO1 are produced. Further, the first production information data shows that the number of components to be mounted on the board is n₁₁ in a case of components P₁, and is n₁₂ in a case of components P₂. When pieces of production information data related to circuit boards of the same board type are input to calculation device 12 at different times, calculation device 12 adds the pieces of data together to update the production information data of storage device 22. Accordingly, the circuit boards of the same board type are collectively produced, and the number of times of work of changing the component feeders is prevented from increasing. In such a case, multiple pieces of time information (for example, Tₐ and T_{b}) are provided, but time information after update can adopt an earliest time among the multiple times (for example, Tₐ).

Calculation device 12 is configured with a computer including CPU 14 and a memory. In accordance with program 16 stored in the memory, CPU 14 executes production order determination processing of determining an order in which the component mounter produce the circuit boards of the multiple board types (WO1, WO2, . . . ) stored in storage device 22. The determination of the production order by calculation device 12 is performed according to a schedule set in advance. For example, the production order of the circuit boards to be produced on a next operation date is determined based on the production information data stored in storage device 22 at a predetermined time every day. Therefore, when production information data is input from input device 20 as needed, the production information data stored in storage device 22 is updated as needed based on the input production information data. Then, at the determined time, the production information data stored in storage device 22 is processed, and the production order of the next operation date is determined.

The production order determined by calculation device 12 is transmitted from calculation device 12 to display device 24 and displayed on display device 24. Display device 24 may be any device as long as a user can check the displayed production order. Calculation device 12 transmits the determined production order to the component mounter. The component mounter produces the circuit boards according to the received production order.

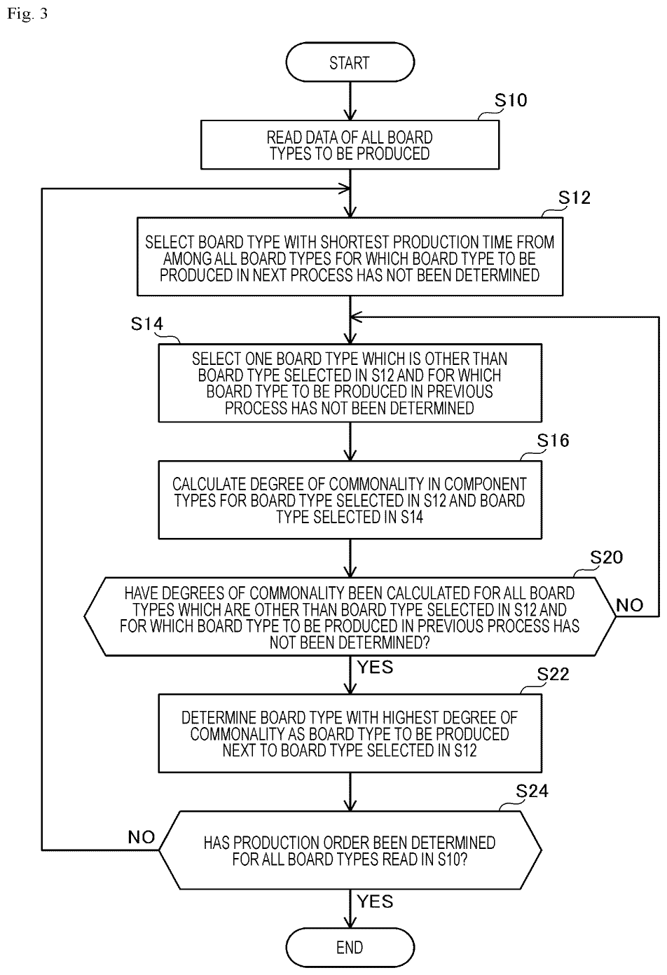

Next, the production order determination processing executed by calculation device 12 will be described in detail. As described above, the production order determination processing is performed according to the schedule set in advance. As shown in FIG. 3, calculation device 12 first reads the production information data stored in storage device 22 (S10). Accordingly, the production order is determined for “the circuit boards of multiple board types” stored in storage device 22 during execution of S10. For example, when the production information data shown in FIG. 2 is stored in storage device 22, calculation device 12 determines the production order for the circuit boards of the board types (WO1, WO2, . . . ).

Next, calculation device 12 selects “the circuit boards of the board type” with the shortest production time from among all “the circuit boards of the board types” for which “the circuit boards of the board type” to be produced in a next process have not been determined (S12). That is, in the circuit boards to be produced by the component mounter, the number (N₁, N₂, . . . ) of production, the component types (P₁, P₂, . . . ) of components to be mounted, and the number (nᵢⱼ) by which the components are mounted are set depending on the board type (WO1, WO2, . . . ). Therefore, it is possible to calculate a time required to produce the circuit boards by the set number (N₁, N₂, . . . ) for each board type (WO1, WO2, . . . ). As described later in detail, in the production order determination processing, when the board type is selected in S12, circuit boards of board type to be produced next to the circuit boards of the selected board type are determined (refer to S22). Accordingly, the production order needs to be determined for “the circuit boards of the board type” for which “the circuit boards of the board type” to be produced in the next process have not been determined. In S12, “the circuit boards of the board type” with the shortest production time are selected from among all “the circuit boards of the board types” for which “the circuit boards of the board type” to be produced in the next process have not been determined. In S12 performed immediately after S10, since “the circuit boards of the board type” to be produced in the next process have not been determined for all “the circuit boards of the board types”, “the circuit boards of the board type” with the shortest production time are selected from among all “the circuit boards of the board types” stored in storage device 22.

Next, calculation device 12 selects one of “the circuit boards of the board type” which are the circuit boards of the board type other than the board type selected in S12, which are producible next to the board type selected in S12, and for which “the circuit boards of the board type” to be produced in a previous process have not been determined (S14), and calculates a degree of commonality in component types for “the circuit boards of the board type” selected in S12 and “the circuit boards of the board type” selected in S14 (S16). As described above, in the production information data, for each board type, the number (N₁, N₂, . . . ) of production, the component types (P₁, P₂, . . . ) of the components to be mounted, and the number (nᵢⱼ) by which the components are mounted are set. Accordingly, for each of “the circuit boards of the board type” selected in S12 and S14, calculation device 12 can calculate the number of the required component feeders for each component type (P₁, P₂, . . . ) and the number of component feeders for each component type (P₁, P₂, . . . ) to be prepared in the component mounter when the production is started. In S16, an extent to which the component feeders for each component type (P₁, P₂, . . . ) to be prepared in the component mounter when the production is started are common is calculated. For example, when the number of component feeders attached to the component mounter is N, and the number of component feeders common between “the circuit boards of the board type” selected in S12 and “the circuit boards of the board type” selected in S14 is Nc, a degree of commonality is calculated as Nc/N.

Next, calculation device 12 determines whether the degree of commonality in S16 has been calculated for all “the circuit boards of the board types” which are other than “circuit boards of the board type” selected in S12, which are producible next to the board type selected in S12, and for which “the circuit boards of the board type” to be produced in the previous process have not been determined (S20). When the degree of commonality in S16 has not been calculated for all “the circuit boards of the board types” (NO in S20), calculation device 12 returns to S14 and repeats processing from S14. Accordingly, the degree of commonality in S16 is calculated for all “the circuit boards of the board types” which are other than “the circuit boards of the board type” selected in S12, which are producible next to the board type selected in S12, and for which “the circuit boards of the board type” to be produced in the previous process have not been determined.

On the other hand, when the degree of commonality in S16 has been calculated for all “the circuit boards of the board types” (YES in S20), calculation device 12 determines “circuit boards of a board type” having the highest degree of commonality as “the circuit boards of the board type” to be produced next to the “circuit boards of the board type” selected in S12 (S22). That is, calculation device 12 determines “the circuit boards of the board type” in which the degree of commonality calculated in S16 is the largest as “the circuit boards of the board type” to be produced next to “the circuit boards of the board type” selected in S12.

Next, calculation device 12 determines whether the production order has been determined for all “the circuit boards of the board types” of the production information data read in S10 (S24). When the production order has not been determined for all “the circuit boards of the board types” (NO in S24), calculation device 12 returns to S12 and repeats the processing from S12. Accordingly, the production order is determined for all “the circuit boards of the board types” stored in storage device 22. On the other hand, when the production order has been determined for all “the circuit boards of the board types” (YES in S24), calculation device 12 ends the production order determination processing.

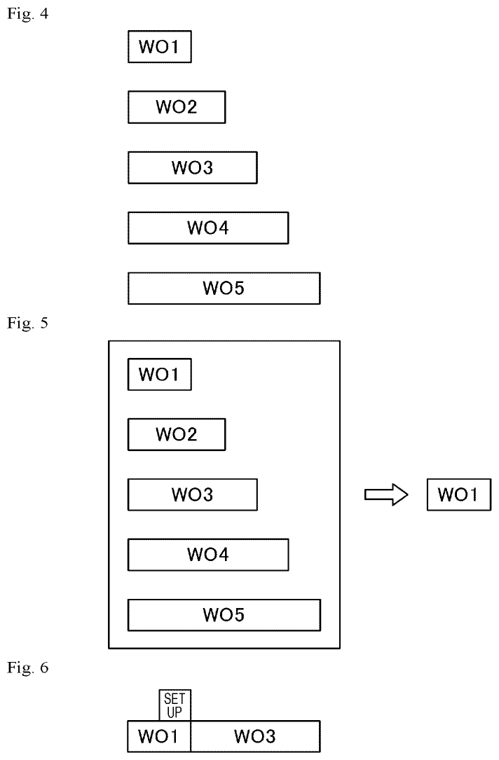

Here, a specific example in which the production order is determined by the execution of the production order determination processing by calculation device 12 will be described with reference to FIGS. 4 to 12. First, as shown in FIG. 4, storage device 22 stores production information data of circuit boards of five types, which are board types WO1, WO2, WO3, WO4, and WO5. In FIG. 4, production times T₁, T₂, T₃, T₄, and T₅ for producing the circuit boards of board types WO1, WO2, WO3, WO4, and WO5 are represented by dimensions in a lateral axis direction. That is, T₁<T₂<T₃<T₄<Ts is satisfied.

First, as shown in FIG. 5, calculation device 12 selects “the circuit boards of board type WO1” with the shortest production time from among circuit boards of five types, which are board types WO1, WO2, WO3, WO4, and WO5. Next, calculation device 12 calculates a degree of commonality in components between “the circuit boards of board type WO1” and each of the circuit boards of four types, which are board types WO2, WO3, WO4, and WO5, for which the circuit boards of the board type to be produced in the previous process have not been determined. Then, calculation device 12 determines “the circuit boards of board type WO3” having the highest degree of commonality in components as the circuit boards to be produced next to the “the circuit boards of board type WO1” (a state shown in FIG. 6). As shown in FIG. 6, since “the circuit boards of board type WO3” have a high degree of commonality in components with respect to “the circuit boards of board type WO1”, preparation work (setup work) for producing “the circuit boards of board type WO3” can be performed in a short time. As a result, the preparation work for producing “the circuit boards of board type WO3” can be completed during production of “the circuit boards of board type WO1”.

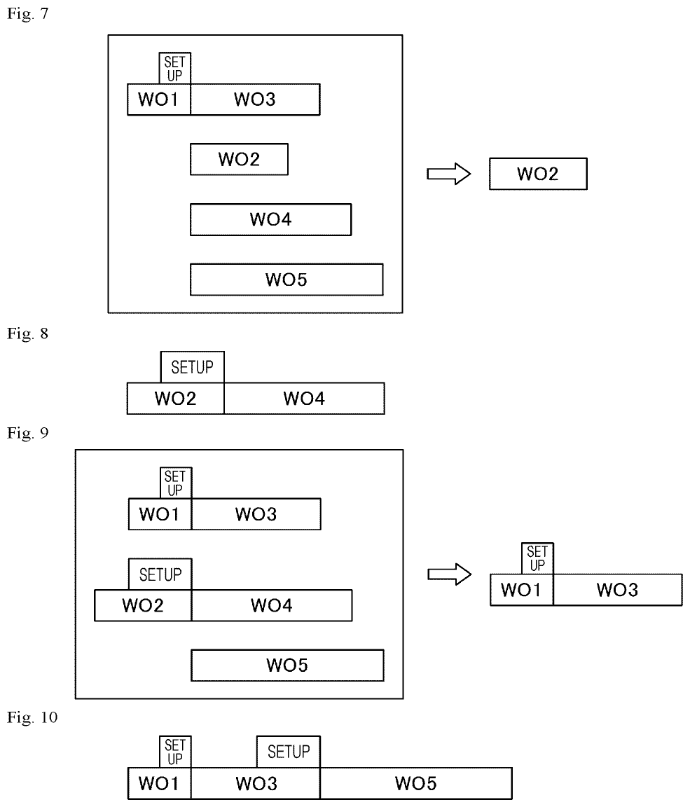

Next, as shown in FIG. 7, calculation device 12 selects “the circuit boards of the board type” with the shortest production time (that is, the circuit boards of board type WO2) from among all “the circuit boards of the board types” (that is, the circuit boards of the four types, which are board types WO3, WO2, WO4, and WO5) for which “the circuit boards of the board type” produced in the next process have not been determined. Next, calculation device 12 calculates a degree of commonality in components between “the circuit boards of board type WO2” which are selected and each of the circuit boards of three types, which are board types WOI, WO4, and WO5, for which the circuit boards of the board type to be produced in the previous process have not been determined. Then, calculation device 12 determines “the circuit boards of board type WO4” having the highest degree of commonality in components as the circuit boards to be produced next to the “the circuit boards of board type WO2” (a state shown in FIG. 8).

Next, as shown in FIG. 9, calculation device 12 selects “the circuit boards of the board type” with the shortest production time (that is, the circuit boards of board type WO3) from among all “the circuit boards of the board types” (that is, the circuit boards of the three types, which are board types WO3, WO4, and WO5) for which “the circuit boards of the board type” produced in the next process have not been determined. Next, calculation device 12 calculates a degree of commonality in components between “the circuit boards of board type WO3” and each of the circuit boards of two types, which are board types WO2 and WO5, for which the circuit boards of the board type to be produced in the previous process have not been determined. Then, calculation device 12 determines “the circuit boards of board type WO5” having the highest degree of commonality in components as the circuit boards to be produced next to the “the circuit boards of board type WO3” (a state shown in FIG. 10).

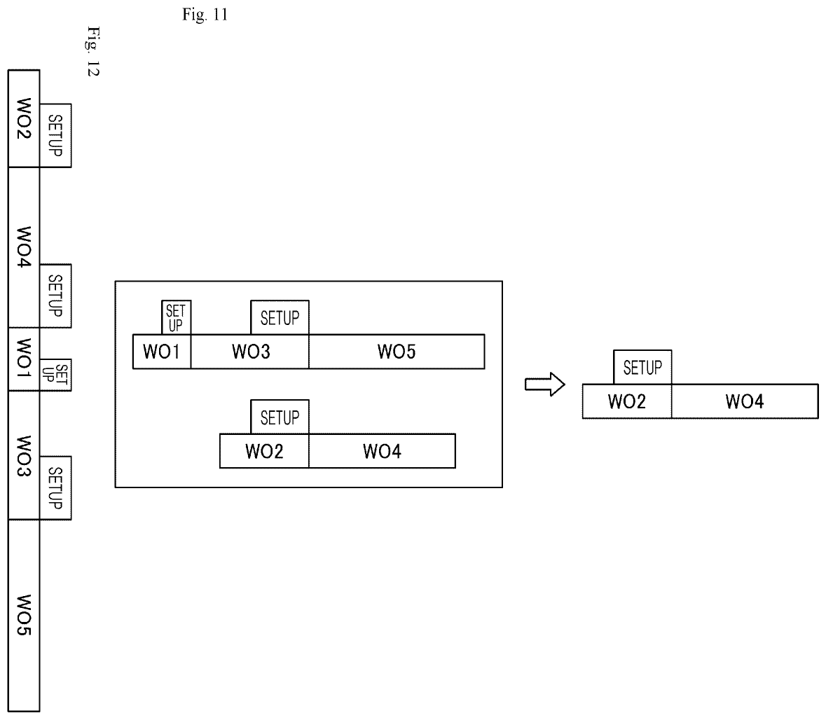

Next, as shown in FIG. 11, calculation device 12 selects “the circuit boards of the board type” with the shortest production time (that is, the circuit boards of board type WO4) from among all “the circuit boards of the board types” (that is, the circuit boards of the two types, which are board types WO4, and WO5) for which “the circuit boards of the board type” produced in the next process have not been determined. When “the circuit boards of board type WO4” are selected, the board type for which the circuit boards of the board type to be produced in the previous process have not been determined is only WO1. Therefore, calculation device 12 determines “the circuit boards of board type WO1” as the circuit boards to be produced next to “the circuit boards of the board type WO4” (a state shown in FIG. 12). Accordingly, the production order of the circuit boards of all board types WO1, WO2, WO3, WO4, and WO5 is determined.

As is clear from the above description, in production order determination system 10 according to the present example, for a circuit board of a board type with a shorter production time, a circuit board of a board type having a higher degree of commonality in components is determined as the circuit board of the board type to be produced next. That is, for a circuit board of a board type with a shorter production time, a circuit board of a board type having a shorter preparation time is determined to be produced next. Therefore, the production preparation of the next circuit board is easily completed during the production of the circuit board of the board type with the short production time. Accordingly, it is possible to reduce the occurrence of an operation stop of the component mounter due to the fact that the production preparation is not completed. Even when the operation of the component mounter needs to be stopped, an operation stop time can be shortened.

In the above-described example, calculation device 12 that executes S12 is an example of a “first circuit board selection section” and a “second circuit board selection section”, and calculation device 12 that executes S14 to S22 is an example of a “first circuit board determination section” and a “second circuit board determination section”.

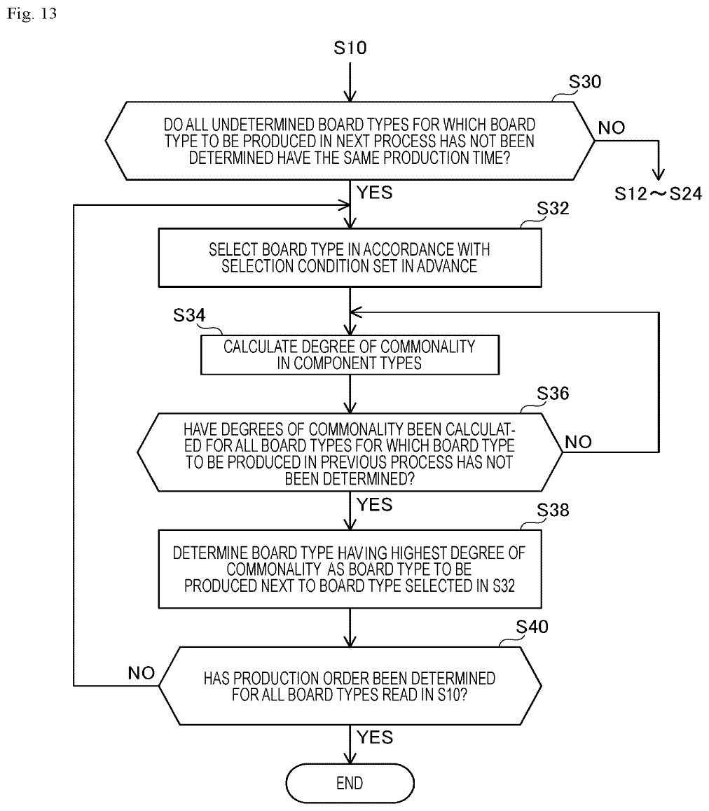

Production order determination system 10 according to the present example has been described above, but the technique disclosed in the present description is not limited to the above-described example. For example, in the above-described example, the production times of the circuit boards differs for all the board types, but the production time of the circuit boards may be the same for some board types. For example, when there are “circuit boards of multiple board types” in which the production times are the same, “circuit boards of one board type” may be selected in accordance with a selection condition set in advance (for example, a degree of priority set in advance), and a production order thereof may be determined in the same manner as in the above-described example. A case where there are “circuit boards of multiple board types” with the longest production time will be described as an example. In this case, for example, as shown in FIG. 13, calculation device 12 determines whether the production times of all “the circuit boards of board types” for which “the circuit boards of the board type” to be produced in the next process have not been determined are the same production time (S30). When the production times of all “the circuit boards of board types” are not the same production time (NO in S30), the processing of S12 to S24 in FIG. 3 (in S24, the processing of determining whether the production order is determined for all “the circuit boards of board types” in which production times are different) is repeated for “the circuit boards of board type” in which production times are different, and the processing returns to S30 in a case of YES in S24. Accordingly, first, the production order is determined for “the circuit boards of the board types” in which the production times are different.

In a case of YES in S30, that is, when the production times of all “the circuit boards of the board types” for which “the circuit boards of the board type” to be produced in the next process have not been determined are the same production time, the processing proceeds to S32, and calculation device 12 selects “the circuit boards of the board type” in accordance with the selection condition set in advance. The selection condition in S32 can be set as desired by the user, and for example, it is possible to select one in which a time when the production information data is input from input device 20 is earliest. By selecting “the circuit boards of the board type” based on the input time, the earliest input production information data is processed (produced) with priority.

When the board type is selected in S32, similarly to the above-described example, the degree of commonality in components between “the circuit boards of the board type” which are selected and “the circuit boards of the board type” for which “the circuit boards of the board type” to be produced in the previous process have not been determined is calculated (S34, S36), and “the circuit boards of the board type” having the highest degree of commonality in components are determined as “the circuit boards of the board type” to be produced next to “the circuit boards of the board type” selected in S32 (S38). Then, calculation device 12 determines whether the production order has been determined for all “the circuit boards of the board types” (S40), and calculation device 12 repeats the processing from S32 until the production order is determined for all “the circuit boards of the board type”. Accordingly, the production order can be determined for all “the circuit boards of the board types”.

In the above-described example, “the circuit boards of the board type” with the shortest production time are selected from among all “the circuit boards of the board types” included in the production information data, and “the circuit boards of the board type” to be produced in the next process are determined with “the circuit boards of the board type” which are selected as the reference, but the technique disclosed in the present description is not limited to the example as above. For example, “the circuit boards of the board type” with the shortest production time may be selected from among all “the circuit boards of the board types” included in the production information data, and the production order may be determined such that “the circuit boards of the board type” which are selected are finally produced. For example, when the component mounter finishes the production of all “the circuit boards of the board type” included in the production information data because of maintenance or the like, it may be determined that the operation of the component mounter is stopped. In such a case, the circuit boards are not produced next to “the circuit boards of the board type” to be finally produced. Accordingly, it is possible to make the setup work unnecessary to perform during the production of “the circuit boards of the board type” with the shortest production time, by determining the production order such that “the circuit boards of the board type” with the shortest production time are finally produced. Even in this case, similarly to the above-described example, after “the circuit boards of the board type” to be finally produced are determined, “the circuit boards of the board type” to be produced next can be determined in order from “the circuit boards of the board type” with the shorter production time.

Although a specific example of the present disclosure has been described in detail above, this is merely illustrative and does not limit the scope of the claims. The technique described in the claims includes various modifications and changes to the specific example described above. The technical elements described in the present description or the drawings exhibit technical usefulness alone or in various combinations and are not limited to the combinations described in the claims as filed. In addition, the technique illustrated in the present description or the drawings can simultaneously achieve multiple objects, and the achievement of one of the objects inherently has technical usefulness.

1. A production order determination system for determining a production order when circuit boards of multiple board types are produced for each board type in an order in a board production facility configured to mount components of multiple types on boards to produce circuit boards, the system comprising:
a first circuit board selection section configured to select a circuit board of a board type with the shortest production time from among the circuit boards of the multiple board types; and
a first circuit board determination section configured to determine a circuit board of a board type to be produced next to the circuit board of the board type selected by the first circuit board selection section,
wherein the first circuit board determination section is configured to
calculate a degree of commonality between component types of multiple components used when the circuit board of the board type selected by the first circuit board selection section is produced and component types of multiple components used when a circuit board of a board type not selected by the first circuit board selection section is produced, for each board type for the circuit board of the board type not selected by the first circuit board selection section, and
determine a circuit board of a board type having the highest calculated degree of commonality in components as the circuit board of the board type to be produced next to the circuit board of the board type selected by the first circuit board selection section.

2. The production order determination system according to claim 1, further comprising:
a second circuit board selection section configured to select, when there are multiple circuit boards of undetermined board types for which a circuit board of a board type to be produced next has not been determined, the circuit board of the board type with the shortest production time from among the multiple circuit boards of the undetermined board types; and
a second circuit board determination section configured to determine a circuit board of a board type to be produced next to the circuit board of the board type selected by the second circuit board selection section,
wherein the second circuit board determination section is configured to
calculate a degree of commonality between component types of multiple components used when the circuit board of the board type selected by the second circuit board selection section is produced and component types of multiple components used when a circuit board of a board type for which a circuit board of a board type to be produced in a previous process is not determined and which is producible next to the circuit board of the board type selected by the second circuit board selection section is produced, for each board type for the circuit board of the board type which is producible, and
determine a circuit board of a board type having the highest calculated degree of commonality in components as the circuit board of the board type to be produced next to the circuit board of the board type selected by the second circuit board selection section.

3. The production order determination system according to claim 2, wherein the selection of the circuit board of the board type performed by the second circuit board selection section and the determination of the circuit board of the board type performed by the second circuit board determination section are repeatedly executed when there are the multiple circuit boards of the undetermined board types for which the circuit board of the board type to be produced next has not been determined.

4. The production order determination system according to claim 1, further comprising:
a third circuit board selection section configured to select, when there are multiple circuit boards of undetermined board types for which a circuit board of a board type to be produced next has not been determined, a circuit board of a certain board type from among the multiple circuit boards of the undetermined board types in accordance with a selection condition set in advance; and
a third circuit board determination section configured to determine a circuit board of a board type to be produced next to the circuit board of the board type selected by the third circuit board selection section,
wherein the third circuit board determination section is configured to
calculate a degree of commonality between component types of multiple components used when the circuit board of the board type selected by the third circuit board selection section is produced and component types of multiple components used when a circuit board of a board type for which a circuit board of a board type to be produced in a previous process is not determined and which is producible next to the circuit board of the board type selected by the third circuit board selection section is produced, for each board type for the circuit board of the board type which is producible, and
determine a circuit board of a board type having the highest calculated degree of commonality in components as the circuit board of the board type to be produced next to the circuit board of the board type selected by the third circuit board selection section.

5. A production order determination system for determining a production order when circuit boards of multiple board types are produced for each board type in an order in a board production facility configured to mount components of multiple types on boards to produce circuit boards, the system comprising:
a circuit board selection section configured to select a circuit board of a board type with the shortest production time from among the circuit boards of the multiple board types; and
a determination section configured to determine the circuit board of the board type selected by the first circuit board selection section as a circuit board of a board type to be finally produced.

6. A production order determination method for determining a production order when circuit boards of multiple board types are produced for each board type in an order in a board production facility configured to mount components of multiple types on boards to produce circuit boards, the method comprising:
a first circuit board selection step of selecting a circuit board of a board type with the shortest production time from among the circuit boards of the multiple board types; and
a first circuit board determination step of determining a circuit board of a board type to be produced next to the circuit board of the board type selected by the first circuit board selection step,
wherein in the first circuit board determination step,
a degree of commonality between component types of multiple components used when the circuit board of the board type selected by the first circuit board selection step is produced and component types of multiple components used when a circuit board of a board type not selected by the first circuit board selection step is produced is calculated for each board type for the circuit board of the board type not selected by the first circuit board selection step, and
a circuit board of a board type having the highest calculated degree of commonality in components is determined as the circuit board of the board type to be produced next to the circuit board of the board type selected by the first circuit board selection step.

7. (canceled)
